(19) United States
(12) Patent Application Publication
(10) Pub. No.: US 2008/0054944 A1
(43) Pub. Date: Mar. 6, 2008

(54) Method and circuit for producing symmetrical output signals tolerant to input timing skew, output delay/slewrate-mismatch, and complementary device mismatch

(75) Inventor: CK Kwon, Boise, ID (US)

Correspondence Address: Edward W. Bulchis, Esq.;DORSEY & WHITNEY LLP, Suite 3400, 1420 Fifth Avenue, Seattle, WA, 98101, US

(73) Assignee: Micron Technology, Inc.

(21) Appl. No.: 11/513,679

(22) Filed: Aug. 30, 2006

(51) Int. Cl. H03K 19/094

(52) U.S. Cl. 326/83

(57) ABSTRACT

An electronic circuit, including a signal transmitter, a signal generator and a ring oscillator, has a topography that is entirely symmetrical so that signals transmitted or produced by the circuit have symmetrical output signals tolerant to input timing skew, output delay/slewrate-mismatch, and complementary device-mismatch. Each P-type transistor in the circuit has a correspondingly connected P-type transistor connected to signal nodes and supply voltage nodes in a complementary manner. Similarly, each N-type transistor in the circuit has a correspondingly connected N-type transistor connected to signal nodes and supply voltage nodes in a complementary manner.

### TECHNICAL FIELD

This invention relates to analog and digital circuits, and, more particularly, to circuits and methods of transmitting and generating symmetrical output signals tolerant to input timing skew, output delay/slewrate-mismatch, and complementary device-mismatch.

### BACKGROUND OF THE INVENTION

Digital signals are commonly coupled to and from electronic devices, such as memory devices, at a high rate of speed. A digital output signal is normally coupled to an analog input buffer or receiver, which generates a digital signal corresponding to the analog or digital signal applied to the input of the receiver. Similarly, repeaters or output buffers are often used to route digital signals to one or more diverse locations in an integrated circuit. The timing at which signals at the outputs of the buffers change state is often critically important for timing the relationships within an integrated circuit. In particular, it is important that the transition of the digital signal not become skewed relative to other digital signals in the electronic device, including the complement of the digital signal. The problems of timing skew or duty error can also be present in other types of circuits, such as ring oscillators, particularly

Timing skew can be created in digital circuits because of a lack of symmetry in such circuits. For example, with reference to FIG. 1, a conventional inverter 10 is formed by a PMOS transistor 12 coupled in series with an NMOS transistor 14. The inverter 10 receives an input signal “IN” and outputs a complementary signal OUT* at the junction of the transistors 12, 14. The rising edge of the OUT* signal is generated by turning the PMOS transistor 12 ON, and the falling edge of the OUT* signal is generated by turning the NMOS transistor 14 ON. However, the switching characteristics of the PMOS transistor 12 may be different from the switching characteristics of the NMOS transistor 14. As a result, the rise time of the OUT* signal may be different from the fall time of the OUT* signal.

The timing skew of a digital signal coupled through an inverter can be reduced to some extent by making the channel width of one of the transistors in the inverter 10 different from the channel width of the other transistor in the inverter 10. For example, the PMOS transistor 12 in the inverter 10 may be fabricated with a channel that is wider than the channel of the NMOS transistor 14. While this approach may provide satisfactory performance in some cases, it is difficult to make the rising edge and falling edge switching characteristics of the inverter equal to each other in the face of process, supply voltage and temperature variations.

One technique for preventing the timing of a digital signal from becoming skewed relative to another digital signal is to use differential signals, which tend to avoid skewing because of their inherent symmetry even where the voltage between which the signals transition is relatively small. However, in many cases, even the use of differential signals does not avoid excessive skewing of digital signals. For example, complementary OUT and OUT* signals are generated from an input signal IN using the circuit 20 shown in FIG. 2. One of the differential signals OUT is generated by coupling the IN signal through two inverters 22, 24 and the other differential signal OUT* is generated by coupling the IN signal through a buffer 26 and an inverter 28. The inverter 22 is formed by a PMOS transistor 30 and an NMOS transistor 32 coupled in series with each other. The PMOS transistor 30 has a relative channel width of 6 while the NMOS transistor 32 has a relative channel width of 4 in an attempt to make the transistors 30, 32 have substantially the same performance. An output of the inverter 22 formed at the junction of the transistors 30, 32 is applied to an input of the second inverter 24, which is also formed by a PMOS transistor 34 coupled in series with an NMOS transistor 36. Insofar as the inverters 22, 24 invert the IN signal twice, the OUT signal generated by the inverter 24 has the same phase as the signal IN.

The buffer 26 formed by an NMOS transistor 40 coupled in parallel with a PMOS transistor 42. The gate of the NMOS transistor 40 is coupled to V_{CC} to maintain the transistor 40 ON, and the gate of the PMOS transistor 42 is coupled to ground to maintain the transistor 42 ON. An output of the buffer 26 is applied to an input of the inverter 28 formed by a PMOS transistor 46 coupled in series with an NMOS transistor 48. Insofar as the buffer 26 and inverter 28 invert the IN signal only once, the OUT* signal output from the inverter 28 is the complement of the IN signal.

Ideally, the transition characteristics of the signals OUT and OUT* should match each other. Unfortunately, the transition characteristics of the OUT and OUT* signals often do not match each other. The OUT signal may transition at a time that is different from the time that the OUT* signal transitions and the rise and fall times of the OUT signal may not match the rise and fall times of the OUT* signal. This lack of symmetry in the transition characteristics of the OUT and OUT* results largely from the lack of symmetry in the circuit 20 shown in FIG. 2. More specifically, the OUT signal is generated by coupling the IN signal through two inverters 22, 24 while the OUT* signal is generated by coupling the IN signal through one buffer 26 and one inverter 28. Yet inverters and buffers have different transition characteristics. As a result, the switching times and propagation times of the OUT signal may be different from those of the OUT* signal.

The problems encountered in generating complementary signals using different types of circuits can be reduced to some extent by using the circuit 50 shown in FIG. 3. The IN signal is applied to a first inverter 52 having three inverter stages, each of which is formed by a PMOS transistor 54 coupled in series with an NMOS transistor 56. An output of the inverter 52 is applied to an input of another inverter 60, which is also formed by a PMOS transistor 64 coupled in series with an NMOS transistor 68. The transistor 64, 68 preferably has channel widths that are greater than the widths of the channels used to fabricate the transistors 54, 56 generally to drive heavy loads. Also, the PMOS transistors 54, 64 preferably have channel widths that are greater than the widths of the channels used to fabricate the NMOS transistors 56, 68, respectively, for the reasons explained above. Also, the transistors 64, 68 have channels that are wider than the channels 54, 56, respectively, in an attempt to provide more symmetrical performance. Insofar as the inverters 52, 60 provide an even number of inversions, the OUT signal generated at the output of the inverter 60 has the same phase as the IN signal.

The IN signal is also applied to a buffer 70. The buffer 70 does not use a PMOS transistor connected to an NMOS transistor in parallel as in the buffer 26 of FIG. 2. Instead, the buffer uses a pair of inverters each of which is formed by a PMOS transistor 72 connected in series with an NMOS transistor 74. The output of the buffer 70 drives an inverter 80, which is also formed by a PMOS transistor 82 connected in series with an NMOS transistor 84. Again, the PMOS transistors 72, 82 have channel widths that are greater than the widths of the channels for the NMOS transistors 74, 84, and the transistors 82, 84 have channels that are wider than the channels 72, 74. Insofar as the buffer 70 and the inverter 80 provide an odd number of inversions, the signal OUT* generated at the output of the inverter 80 is the complement of the IN signal.

By using only inverters and all of the circuitry generating the OUT and OUT*signals, the circuit 50 provides more symmetrical performance than the circuit 20 shown in FIG. 2. However, the propagation delays and slew rates of the signals OUT and OUT* may still not be sufficiently symmetrical to provide adequate performance in many cases, thereby resulting in signal skews. This limited performance is primarily caused by a lack of symmetry in the circuit 50. Not only are different types of transistors, i.e., PMOS and NMOS transistors, used to generate the different transitions, i.e., rising and falling edges, of the OUT and OUT* signals, but the number of inverters used in the inverter 52 differ from the number of inverters used in the buffer 70.

Signals skew resulting from a lack of circuit symmetry is also present in other types of circuits. For example, a ring oscillator 90 shown in FIG. 4 uses three inverters 92, 94, 96 connected in series with each other, with the output of the inverter 96 being fed back to the input of the inverter 92. The output of the ring oscillator 90 is then taken at the output of the inverter 96 through two series connected inverters 98, 100. The use of an odd number of inverters connected in series in a loop produces an unstable condition that results in oscillation. However, the lack of symmetry of the inverters 92-100, as well as a lack of symmetry in the circuit 90, itself may cause the output signal to have different rise and fall times and a duty cycle of other than 50 percent.

A more complex ring oscillator 110 the shown in FIG. 5. The ring oscillator 110 includes four inverters 112, 114, 116, 118 connected in series with each other to form output nodes at the junctions between each pair of interconnected inverters. The output nodes are connected to respective output terminals by respective series-connected output inverters 120,122. A pair of back-to-back inverters, i.e. inverter latches, 126, 128 are connected between two of the complementary output nodes and a second pair of back-to-back inverters 130,132 are connected between the remaining two complementary output nodes. The circuit topography of the ring oscillator 110 results in several loops being formed of three inverters connected with each other. For example, one loop of interconnected inverters includes inverters 116, 118 and 126. A similar loop of inverters includes inverters 112, 114 and 128. Another loop of interconnected inverters includes inverters 114, 116 and 130, and a similar loop includes inverters 118, 112 and 132. The presence of these odd number of inverter loops results in an unstable condition that causes oscillation. Because of the symmetry of the ring oscillator 110, the signals generated at the output nodes are, ideally, phased in quadrature with each other. However, because of the lack of symmetry of the inverters as well as the lack of complete symmetry in the ring oscillator topography itself, the output signals may be skewed so that they are not precisely in quadrature, and the rise and fall times of the output signals may differ.

For an inverter, a buffer and other applicable circuits, it is desirable to produce symmetrical output signals tolerant to timing slew, delay/slewrate-mismatch, and complementary device mismatch.

### SUMMARY OF THE INVENTION

An electronic circuit and method includes a plurality of PMOS transistors and a plurality of NMOS transistors, and it is supplied with power through first and second supply voltage nodes. For each PMOS transistor in the circuit that has a source connected to the first supply voltage node, the drain of a correspondingly connected PMOS transistor is connected to the second supply voltage node. Similarly, for each NMOS transistor having a source connected to the second supply voltage node, the drain of a correspondingly connected NMOS transistor is connected to the first supply voltage node.

### BRIEF DESCRIPTION OF THE DRAWINGS

FIG. 1 is a schematic diagram of a conventional inverter circuit.

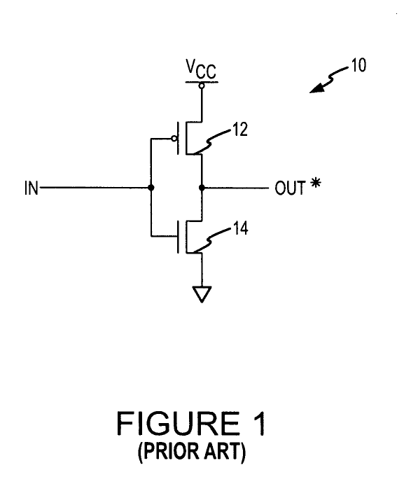

FIG. 2 is a schematic diagram of a conventional circuit for generating complementary signals using a buffer and an inverter.

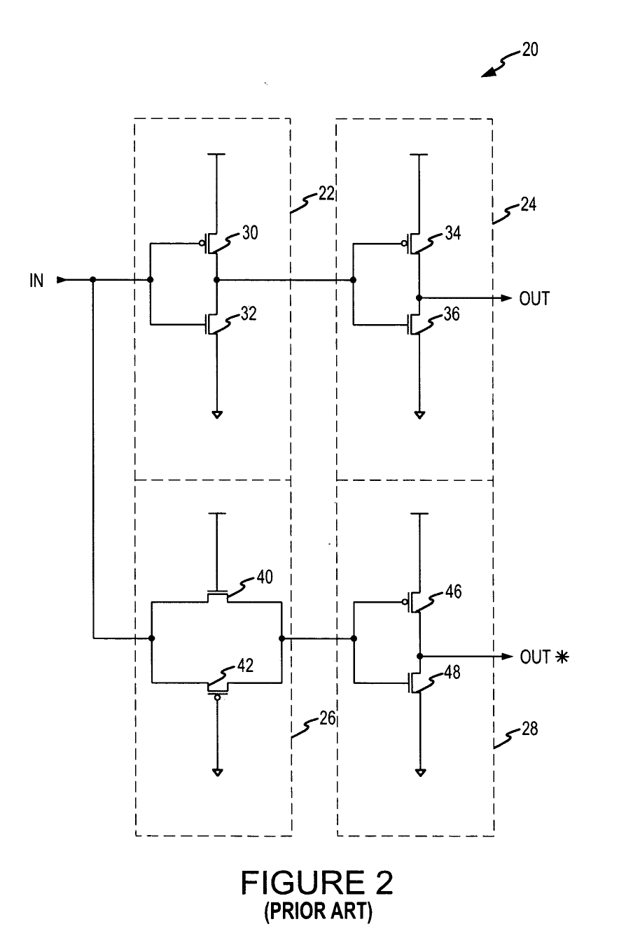

FIG. 3 is a schematic diagram of a conventional circuit for generating complementary signals using only inverters.

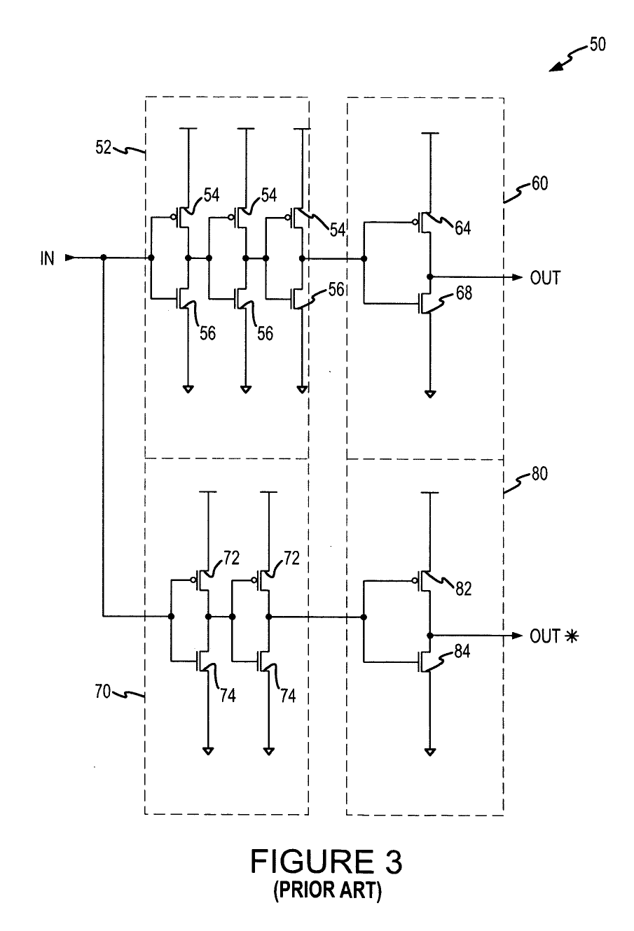

FIG. 4 is a logic diagram of a conventional ring oscillator using inverters.

FIG. 5 is a logic diagram of a conventional ring oscillator using inverters to generate quadrature output signals.

FIG. 6 is a schematic diagram of a signal transmitter circuit for generating complementary signals with minimal timing skew according to one example of the invention.

FIG. 7 is a schematic diagram of a signal transmitter circuit for generating complementary signals with minimal timing skew according to another example of the invention.

FIG. 8 is a logic diagram of a ring oscillator according to one example of the invention.

FIG. 9 is a logic diagram of a ring oscillator to generate quadrature output signals according to another example of the invention.

FIG. 10 is a schematic diagram of a signal generator circuit for generating complementary signals with minimal timing skew from a single ended input signal.

FIG. 11 is a block diagram of a synchronous memory device including signal transmitters and ring oscillators according to one example of the invention.

FIG. 12 is a block diagram of a computer system including the synchronous memory device of FIG. 11.

### DETAILED DESCRIPTION

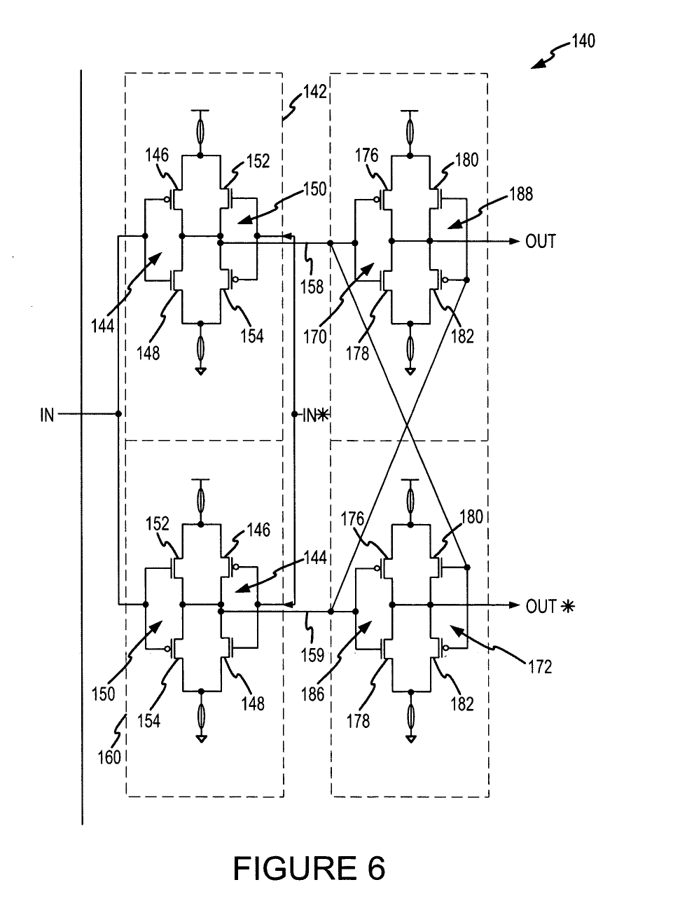

A circuit 140 for transmitting complementary signals according to one example of the invention is shown in FIG. 6. The circuit 140 includes a first circuit 142 having an inverter 144 formed by a PMOS transistor 146 in series with an NMOS transistor 148 that receive an input signal IN at their gates. The first circuit 142 also includes a buffer 150 formed by an NMOS transistor 152 coupled in series with a PMOS transistor 154. The buffer 150 receives the complement of the IN signal, i.e., IN*. An output terminal 158 of the first circuit 142 is connected to both an output of the inverter 144 and an output of the buffer 150.

In operation, the inverter 144 drives the output terminal 158 in the opposite direction from the IN signal. On the other hand, the buffer 150 drives the output terminal in the same direction as the IN* signal. However, since the IN* signal is the complement of the IN signal, both the inverter 144 and the buffer 150 drive the output terminal 158 in the opposite direction from the IN signal and in the same direction as the IN*signal.

The IN and IN*signals are also applied to a second circuit 160 that has a topography that mirrors the topography of the first circuit 142. Therefore, the components in the second circuit 160 corresponding to the same components in the first circuit 142 have been provided with the same reference numerals. Insofar as the IN signal is applied to the buffer 150 and the IN* signal is applied to the inverter 144 of the second circuit 160, both the inverter 144 and the buffer 150 drive the output terminal 159 in the same direction as the IN signal and in the opposite direction from the IN*signal. Therefore, the signal at the output terminal 158 of the first circuit 142 is the compliment of the signal at the output terminal 159 of the second circuit 160.

The transmitter circuit 140 is able to output highly symmetrical signals because of the high degree of symmetry in the topography of the circuit 140. More specifically, the IN signal is applied to both the inverter 144 of the first circuit 142 and the buffer 150 of the second circuit 160. Similarly, the IN* signal is applied to both the inverter 144 of the second circuit 160 and the buffer 150 of the first circuit 142. Thus, both the IN and the IN* signals are applied to exactly the same circuits. Furthermore, both circuits 142, 160 are composed of exactly the same components, which, as explained above, are mirror images of each other in schematics, while their layouts can be placed in the same direction on any axis of symmetry.

With further reference to FIG. 6, the signal generated at the output terminal 158 of the first circuit 142 is applied to the input of an inverter 170 and to the input of a buffer 172. The inverter 170 is formed by a PMOS transistor 176 coupled in series with an NMOS transistor 178 between a supply voltage and ground. The buffer 172 is formed by an NMOS transistor 180 coupled in series with a PMOS transistor 182 between the supply voltage and ground. Similarly, the signal generated at the output terminal 159 of the second circuit 160 is applied to the input of an inverter 186 and to the input of a buffer 188. Again, the inverter 186 is formed by a PMOS transistor 176 coupled in series with an NMOS transistor 178 between a supply voltage and ground. The buffer 188 is formed by an NMOS transistor 180 coupled in series with a PMOS transistor 182 between the supply voltage and ground. Thus, the output terminal 158 of the first circuit 142 drives an inverter 170 formed by a PMOS transistor 176 and an NMOS transistor 178, and a buffer 172 formed by an NMOS transistor 180 and a PMOS transistor 182. Similarly, the output terminal 159 of the second circuit 160 also drives an inverter 186 formed by a PMOS transistor 176 and an NMOS transistor 178 as well as a buffer 188 formed by an NMOS transistor 180 and a PMOS transistor 182. The circuits driven by the first circuit 142 are thus identical to the circuits driven by the second circuit 160. This complete symmetry causes the signals generated by the circuit 140 to be entirely symmetrical.

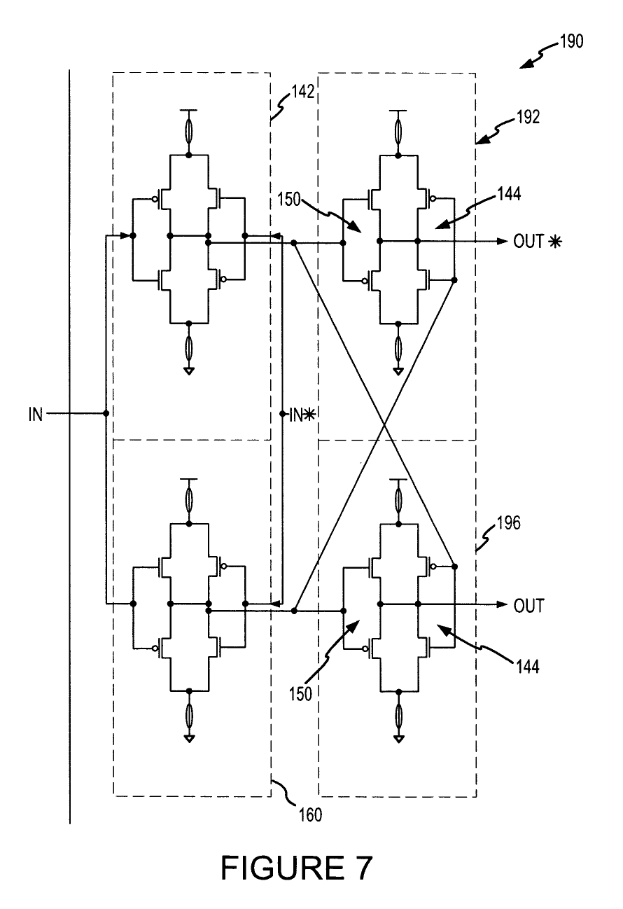

A transmitter circuit 190 according to another example of the invention is shown in FIG. 7. The transmitter circuit 190 includes the circuit 142 & 160 used in the transmitter circuit 140 of FIG. 6, which generates complementary signals at its outputs. The signals are applied to a second circuit 192, 196 that are identical to the buffer circuit 160 shown in FIG. 6. As explained above, each of the buffer circuits 192, 196 includes an inverter 144 and a buffer 150. Again, both the first circuit 142 & 160 and the second circuit 192, 196 are entirely symmetrical so that a differential signal generated at the outputs of the circuits 190 is entirely symmetrical without any signal skews.

Although the transmitter circuits 140, 190 of FIGS. 6 and 7, respectively, are used to generate complementary output signals from complementary input signals, it will be understood that other functions are possible. For example, one of the input signals can be simply a DC reference voltage, such as one-half the supply voltage. In such case, the transmitter circuits 140, 190 will convert a single-ended signal to complementary signals.

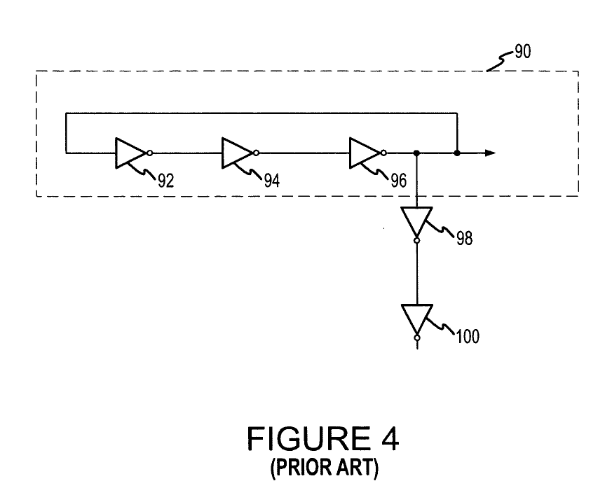

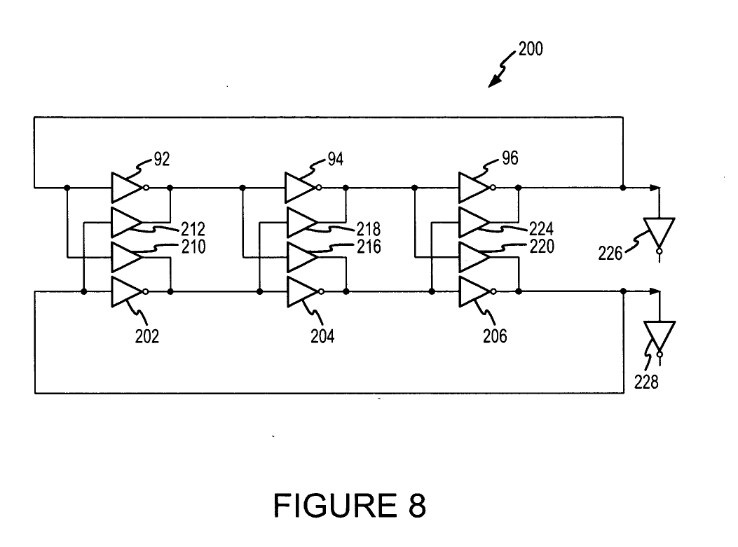

A ring oscillator 200 according to one example of the invention is shown in FIG. 8. The ring oscillator 200 is similar to the ring oscillator 90 shown in FIG. 4 in that it uses the same three inverters 92, 94, 96 connected in series with each other that were used in the ring oscillator 90. Again, the output of the inverter 96 is fed back to the input of the inverter 92. To provide symmetrical performance, a second loop is used, which is formed by three inverters 202, 204, 206 connected in series with each other with the output of the inverter 206 fed back to the input of the inverter 202. The input to the inverter 92 is applied to a buffer 210 that is coupled to the output of the inverter 202. Similarly, the input to the inverter 202 is applied to a buffer 212 that is coupled to the output of the inverter 92. In the same manner, the output of the inverter 92 is coupled through a buffer 216 to the output of the inverter 204, and the output of the inverter 202 is coupled through a buffer 218 to the output of the inverter 94. Also, the output of the inverter 94 is coupled through a buffer 220 to the output of the inverter 206, and the output of the inverter 204 is coupled through a buffer 224 to the output of the inverter 96. Complementary outputs are then taken from the outputs of the inverter 96, 206 through respective inverters 226, 228, respectively. Again, this complete symmetry present in the ring oscillator 200 causes the signal generated at the output of the inverters 226, 228 to be entirely symmetrical despite variations in process, supply voltage and temperature.

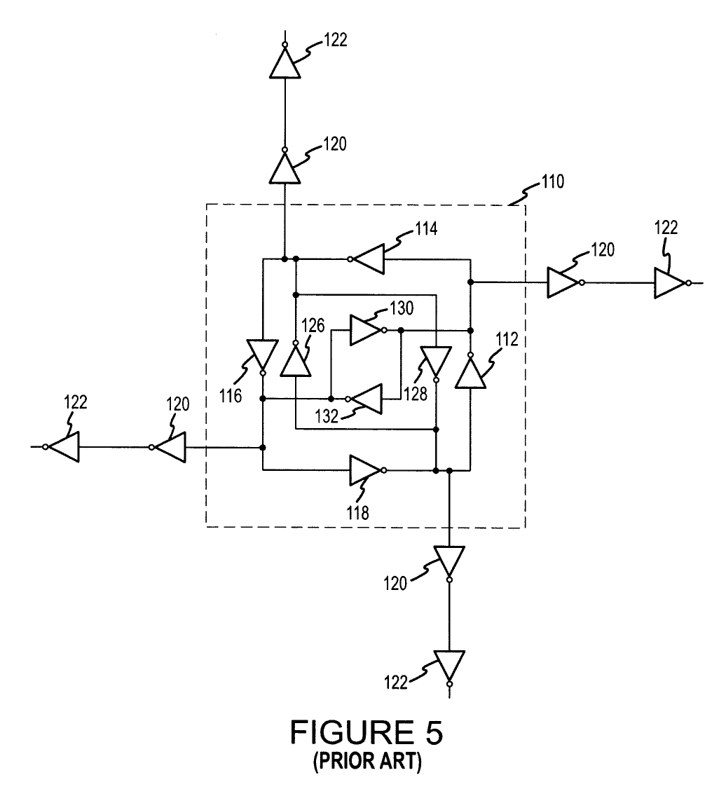

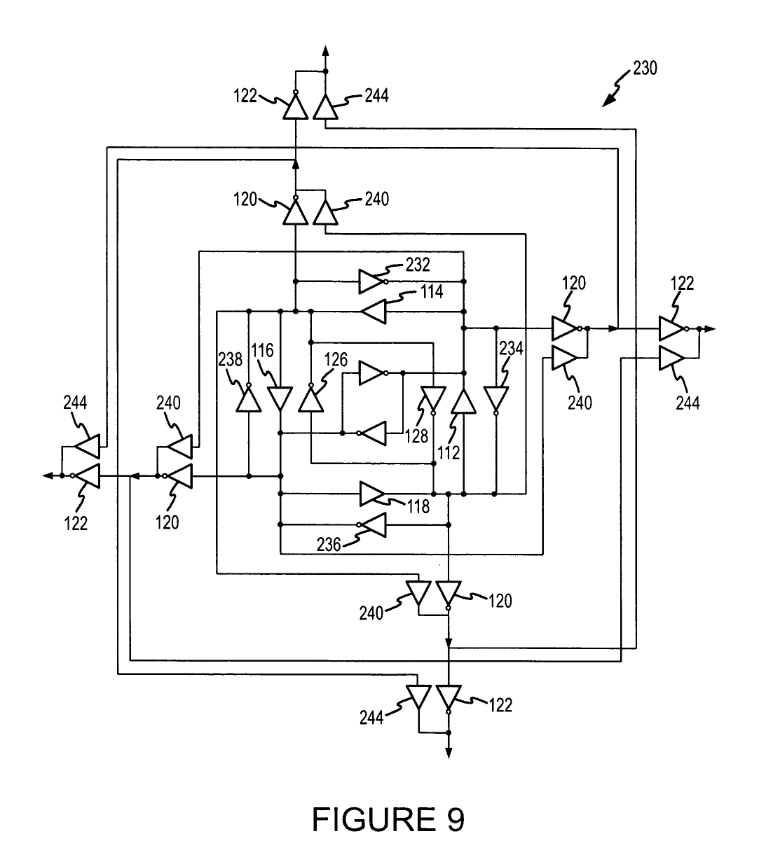

Another ring oscillator 230 according to one example of the invention is shown in FIG. 9. The ring oscillator 230 is more symmetrical version of the ring oscillator 110 shown in FIG. 5. The basic components of the ring oscillator 230 that are identical to components in the ring oscillator 110 have therefore been provided. To make the topography of the ring oscillator 230 entirely symmetrical, as well as faster, inverters 232, 234, 236, 238 have been connected in back-to-back configuration with the buffers 114, 112, 118, 116, respectively. Also, buffers 240 have been coupled to the outputs of respective inverters 120, and buffers 244 have been coupled to the outputs of respective inverters 122. The complete symmetry of the topology used in the ring oscillator 230 causes the signals generated at the outputs of the ring oscillator 230 to be substantially free of any mismatch.

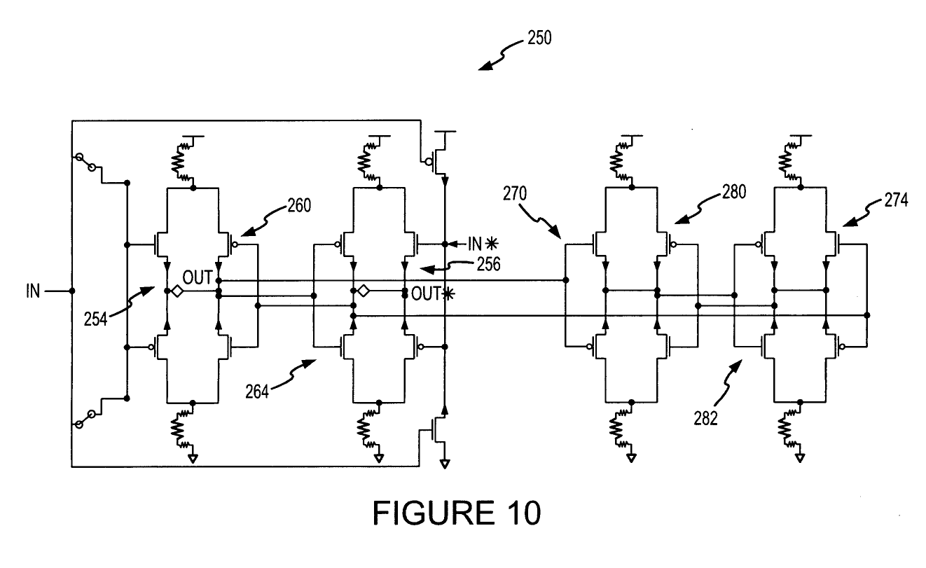

Based on the inverters and buffers shown in FIGS. 6 and 7, a signal generator 250 according to another example of the invention is shown in FIG. 10. A first buffer 254 receives an input signal IN, and a second buffer 256 receives a complementary input signal IN*, which may have a timing that is skewed with respect to the signal IN. A first pair of inverters 260, 264 are coupled in opposite directions between complementary output terminals OUT and OUT* to form a positive feedback latch. The OUT and OUT* terminals are coupled to a second circuit like that described above formed by buffers 270, 274 and a pair of inverters 280, 282 coupled to form a positive feedback latch. By using inherent differential symmetrical structures or additional positive/negative feedback circuits per stage as well as between input stages and output stages as shown in FIG. 10, the signal generator 250 can make the output signals symmetrical to each other, in terms of delay, slew rate, and self-induced duty-cycle error.

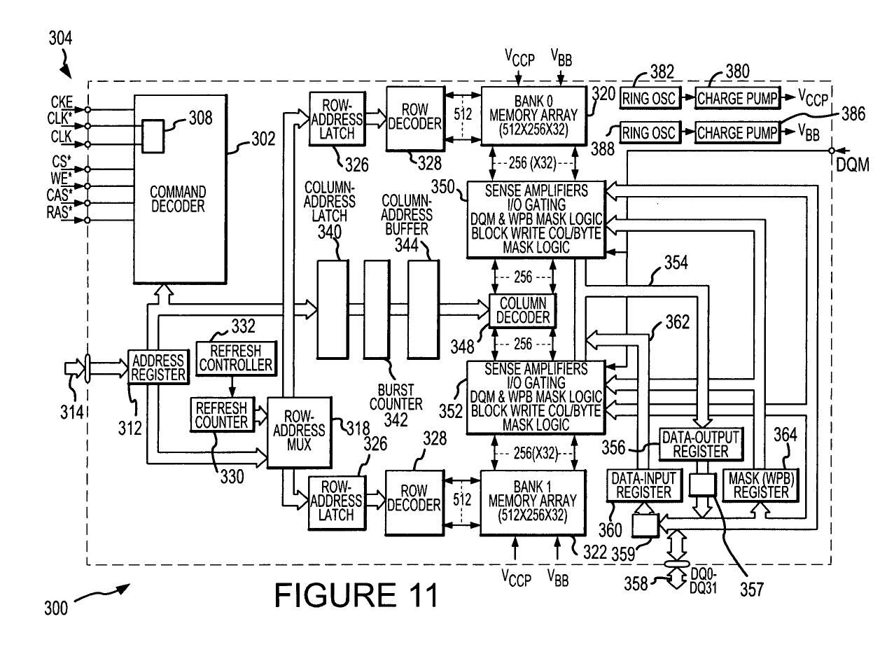

A signal generator or transmitter according to various examples of the invention can be used in a wide variety of analog or digital circuits, including a memory device 300 as shown in FIG. 11. Further, ring oscillators according to various examples of the invention can also be used in a wide variety of digital circuits, including the memory device 300. The memory device 300 illustrated in FIG. 11 is a synchronous dynamic random access memory (“SDRAM”), although the invention can be embodied in other types of DRAMs, such as packetized DRAMs and RAMBUS DRAMs (RDRAMS”), as well as other types of digital devices. The SDRAM 300 includes a command decoder 302 that controls the operation of various components within the SDRAM during operation. The command decoder 302 generates control signals responsive to command signals received on a control bus 304, with these command signals including complementary clock signals CLK, CLK* that are received by a signal transmitter 308 according to one example of the invention. A memory controller (not shown) typically generates these commands signals, which typically include a clock enable signal CKE*, a chip select signal CS*, a write enable signal WE*, a row address strobe signal RAS*, and a column address strobe signal CAS*, in addition to the CLK, CLK* signals.

The SDRAM 300 further includes an address register 312 that receives either a row address or a column address on an address bus 314, which is generally coupled to the memory controller (not shown). Typically, a row address is initially received by the address register 312 and applied to a row address multiplexer 318. The row address multiplexer 318 couples the row address to a number of components associated with either of two memory banks 320, 322 depending upon the state of a bank address bit forming part of the row address. Associated with each of the memory banks 320, 322 is a respective row address latch 326, which stores the row address, and a row decoder 328, which applies various signals to its respective array 320 or 322 as a function of the stored row address. The row address multiplexer 318 also couples row addresses to the row address latches 326 for the purpose of refreshing the memory cells in the arrays 320, 322. The row addresses are generated for refresh purposes by a refresh counter 330, which is controlled by a refresh controller 332.

After the row address has been applied to the address register 312 and stored in one of the row address latches 326, a column address is applied to the address register 312. The address register 312 couples the column address to a column address latch 340. Depending on the operating mode of the SDRAM 300, the column address is either coupled through a burst counter 342 to a column address buffer 344, or to the burst counter 342 which applies a sequence of column addresses to the column address buffer 344 starting at the column address output by the address register 312. In either case, the column address buffer 344 applies a column address to a column decoder 348 which applies various signals to respective sense amplifiers and associated column circuitry 350, 352 for the respective arrays 320, 322.

Data to be read from one of the arrays 320, 322 is coupled to the column circuitry 350, 352 for one of the arrays 320, 322, respectively. The data is then coupled through a read data path 354 to a data output register 356 through a signal transmitter 357 according to one example of the invention, which applies the data to a data bus 358. Data to be written to one of the arrays 320, 322 is coupled from the data bus 358 through a signal transmitter 359 according to one example of the invention to a data input register 360. From the data input register 360, the write data are coupled through a write data path 362 to the column circuitry 350, 352 where they are transferred to one of the arrays 320, 322, respectively. A mask register 364 may be used to selectively alter the flow of data into and out of the column circuitry 350, 352, such as by selectively masking data to be read from the arrays 320, 322. In addition to the CLK, CLK* signals, and the write data signals, other signals received by the SDRAM 300 or other digital circuit could also be received through respective signal transmitters or symmetrical output signals could also be generated and sent to the bus 358, synchronously to the CLK/CLK*, according to various examples of the invention.

As previously mentioned, the above-described operation of the SDRAM 300 is controlled by the command decoder 302 responsive to command signals received on the control bus 304. Various combinations of these signals are registered as respective commands, such as a read command or a write command. The command decoder 302 generates a sequence of control signals responsive to the command signals to carry out the function (e.g., a read or a write) designated by each of the command signals. These command signals, and the manner in which they accomplish their respective functions, are conventional. Therefore, in the interest of brevity, a further explanation of these control signals will be omitted.

As is well-known in the art, it is typical to supply the arrays 320, 322 with a voltage V_{CCP} that has a magnitude greater than the magnitude of a supply voltage V_{CC} coupled to the memory device 300. For example, the voltage V_{CCP} may be used to increase the magnitude of a wordline voltage applied to wordlines (not shown) in the arrays 320, 322. As is also well-known in the art, it is typical to supply the substrates for the arrays 320, 322 with a slight negative voltage V_{BB} to minimize the leakage of access transistors (not shown) used in the arrays 320, 322. The voltage V_{CCP} is produced by a charge pump 380, which receives a periodic signal from a ring oscillator 382 according to various examples of the invention. Similarly, the voltage V_{BB} is produced by a charge pump 386, which receives a periodic signal from a ring oscillator 388 according to various examples of the invention.

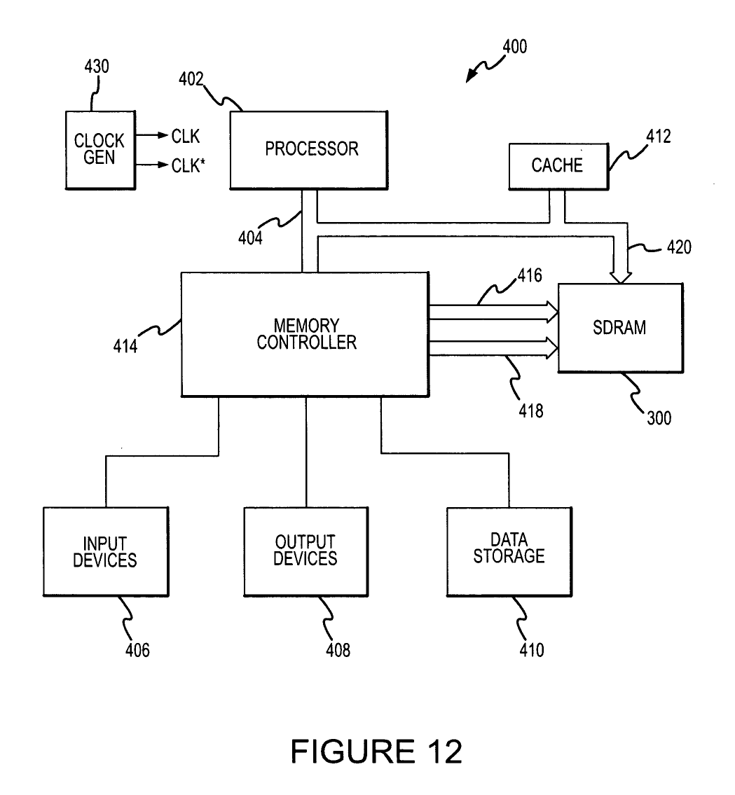

FIG. 12 shows a computer system 400 containing the SDRAM 300 of FIG. 11. The computer system 400 includes a processor 402 for performing various computing functions, such as executing specific software to perform specific calculations or tasks. The processor 402 includes a processor bus 404 that normally includes an address bus, a control bus, and a data bus. In addition, the computer system 400 includes one or more input devices 406, such as a keyboard or a mouse, coupled to the processor 402 to allow an operator to interface with the computer system 400. Typically, the computer system 400 also includes one or more output devices 408 coupled to the processor 402, such output devices typically being a printer or a video terminal. One or more data storage devices 410 are also typically coupled to the processor 402 to allow the processor to store data in or retrieve data from internal or external storage media (not shown). Examples of typical storage devices 410 include hard and floppy disks, tape cassettes, and compact disk read-only memories (CD-ROMs). The processor 402 is also typically coupled to cache memory 412, which is usually static random access memory (“SRAM”), and to the SDRAM 300 through a memory controller 414. The memory controller 414 normally includes a control bus 416 and an address bus 418 that are coupled to the SDRAM 300. A data bus 420 is coupled from the SDRAM 300 to the processor bus 404 either directly (as shown), through the memory controller 414, or by some other means.

The timing of any signal used in the computer system 400 can be improved by a ring oscillator or a signal transmitter according to various examples of the invention.

Although the present invention has been described with reference to the disclosed embodiments, persons skilled in the art will recognize that changes may be made in form and detail without departing from the spirit and scope of the invention. Such modifications are well within the skill of those ordinarily skilled in the art. Accordingly, the invention is not limited except as by the appended claims.

We claim:

1. A transmitter for complementary first and second input signals, comprising:
a first P-type or N-type transistor having a gate connected to receive the first input signal, a source or drain connected to a first supply voltage and the other drain or source connected to an output terminal; and
a second P-type or N-type transistor substantially identical to the first transistor having a gate connected to receive the second input signal, a source or drain connected to the output terminal, and the other drain or source connected to a second supply voltage.

2. A transmitter for complementary first and second input signals, comprising:
a first inverter having an input receiving the first input signal, the first inverter having an output terminal;
a first buffer having an input receiving the second input signal, the first buffer having an output terminal coupled to the output terminal of the first inverter;
a second inverter that is substantially identical to the first inverter, the second inverter having an input receiving the second input signal, the second inverter having an output terminal; and
a second buffer that is substantially identical to the first buffer, the second buffer having an input receiving the first input signal, the second buffer having an output terminal coupled to the output terminal of the second inverter.

3. The transmitter of claim 2, wherein each of the first and second inverters comprise:
a P-type transistor having a source connected to a first supply voltage and a drain connected to the output terminal of the inverter; and
an N-type transistor having a drain connected to the output terminal of the inverter and a source connected to a second supply voltage, the second supply voltage having a magnitude that is less than the magnitude of the first supply voltage.

4. The transmitter of claim 2, wherein each of the first and second buffers comprise:
an N-type transistor having a drain connected to a first supply voltage and a source connected to the output terminal of the buffer; and
a P-type transistor having a source connected to the output terminal of the buffer and a drain connected to a second supply voltage, the second supply voltage having a magnitude that is less than the magnitude of the first supply voltage.

5. The transmitter of claim 2, further comprising:
a third inverter having an input coupled to the output terminal of the first inverter and the output terminal of the first buffer, the third inverter having an output terminal;
a third buffer having an input coupled to the output terminal of the second inverter and the output terminal of the second buffer, the third buffer having an output terminal coupled to the output terminal of the third inverter;
a fourth inverter having an input coupled to the output terminal of the second inverter and the output terminal of the second buffer, the fourth inverter having an output terminal; and
a fourth buffer having an input coupled to the output terminal of the first inverter and the output terminal of the first buffer, the fourth buffer having an output terminal coupled to the output terminal of the fourth inverter.

6. The transmitter of claim 2, further comprising:
a third buffer having an input coupled to the output terminal of the first inverter and the output terminal of the first buffer, the third buffer having an output terminal;
a third inverter having an input coupled to the output terminal of the second inverter and the output terminal of the second buffer, the third inverter having an output terminal coupled to the output terminal of the third buffer;
a fourth buffer having an input coupled to the output terminal of the second inverter and the output terminal of the second buffer, the fourth buffer having an output terminal; and
a fourth inverter having an input coupled to the output terminal of the first inverter and the output terminal of the first buffer, the fourth inverter having an output terminal coupled to the output terminal of the fourth buffer.

7. A transmitter for complementary first and second input signals, comprising:
a first buffer having an input receiving the first input signal, the first buffer having an output coupled to a first output terminal;
a first inverter having an input, the first inverter having an output coupled to the first output terminal;
a second buffer that is substantially identical to the first buffer, the second buffer having an input receiving the second input signal, the second buffer having an output coupled to a second output terminal and to the input of the first inverter; and
a second inverter that is substantially identical to the first inverter, the second inverter having an input coupled to the first output terminal, the second inverter having an output coupled to the second output terminal.

8. The transmitter of claim 7 wherein each of the first and second inverters comprise:
a P-type transistor having a source connected to a first supply voltage and a drain connected to the output terminal of the inverter; and
an N-type transistor having a drain connected to the output terminal of the inverter and a source connected to a second supply voltage, the second supply voltage having a magnitude that is less than the magnitude of the first supply voltage.

9. The transmitter of claim 7, further comprising:
a third buffer having an input coupled to the first output terminal, the third buffer having an output coupled to a third output terminal;
a third inverter having an input, the third inverter having an output coupled to the third output terminal;
a fourth buffer that is substantially identical to the third buffer, the fourth buffer having an input coupled to the second output terminal, the fourth buffer having an output coupled to a fourth output terminal and to the input of the third inverter; and
a fourth inverter that is substantially identical to the third inverter, the fourth inverter having an input coupled to the third output terminal, the fourth inverter having an output coupled to the fourth output terminal.

10. The transmitter of claim 9 wherein the second input signal comprises a DC reference voltage.

11. The transmitter of claim 9, further comprising an inverter having an input coupled to receive the first input signal, the inverter having an output that provides the second input signal.

12. The transmitter of claim 9 wherein the first output terminal is coupled to the third output terminal, and the second output terminal is coupled to the fourth output terminal.

13. A transmitter for complementary first and second input signals, comprising:
a first P-TYPE transistor having a gate coupled to receive the first input signal, a source connected to a first supply voltage, and a drain connected to a first output terminal;
a second P-type transistor having a gate coupled to receive the first input signal, a drain connected to a second supply voltage, and a source connected to a second output terminal, the second supply voltage having a magnitude that is less than the magnitude of the first supply voltage;
a first N-type transistor having a gate coupled to receive the first input signal, a source connected to the second supply voltage, and a drain connected to the first output terminal;
a second N-type transistor having a gate coupled to receive the first input signal, a drain connected to the first supply voltage, and a source connected to the second output terminal;
a third N-type transistor having a gate coupled to receive the second input signal, a drain connected to the first supply voltage, and a source connected to a third output terminal;
a fourth N-type transistor having a gate coupled to receive the second input signal, a drain connected to a fourth output terminal, and a source connected to the second supply voltage;
a third P-type transistor having a gate coupled to receive the second input signal, a source connected to the third output terminal, and a drain connected to the second supply voltage; and
a fourth P-type transistor having a gate coupled to receive the second input signal, a drain connected to the fourth output terminal, and a source connected to the second supply voltage.

14. The transmitter of claim 13 wherein the first output terminal is coupled to the third output terminal, and the second output terminal is coupled to the fourth output terminal.

15. A transmitter for complementary first and second input signals, comprising:
a first P-type transistor having a gate coupled to a second output terminal, a source connected to a first supply voltage, and a drain connected to a first output terminal;
a first N-type transistor having a gate coupled to the second output terminal, a source connected to a second supply voltage, and a drain connected to the first output terminal, the second supply voltage having a magnitude that is less than the magnitude of the first supply voltage;
a second P-type transistor having a gate coupled to receive the first input signal, a drain connected to the second supply voltage, and a source connected to a first output terminal;
a second N-type transistor having a gate coupled to receive the first input signal, a drain connected to the first supply voltage, and a source connected to the first output terminal;
a third P-type transistor having a gate coupled to receive the second input signal, a drain connected to the second supply voltage, and a source connected to a second output terminal;
a third N-type transistor having a gate coupled to receive the second input signal, a drain connected to the first supply voltage, and a source connected to the second output terminal;
a fourth P-type transistor having a gate coupled to a first output terminal, a source connected to the first supply voltage, and a drain connected to a second output terminal;
a fourth N-type transistor having a gate coupled to the first output terminal, a source connected to the second supply voltage, and a drain connected to the second output terminal.

16. An electronic circuit having a plurality of P-type transistors, a plurality of N-type transistors, a first supply voltage node, and a second supply voltage node, the electronic circuit having, for each P-type transistor having a source connected to the first supply voltage node, a correspondingly connected P-type transistor having a drain connected to the second supply voltage node, the electronic circuit further having, for each N-type transistor having a source connected to the second supply voltage node, a correspondingly connected N-type transistor having a drain connected to the first supply voltage node.

17. The electronic circuit of claim 16 wherein the electronic circuit comprises a signal transmitter or generator.

18. The electronic circuit of claim 16 wherein the electronic circuit comprises a ring oscillator.

19. The electronic circuit of claim 16, further comprising a first input node connected to the gate of a P-type transistor having its source connected to the first supply voltage node and to the gate of a P-type transistor having its drain connected to the second supply voltage node, the first input node further being connected to the gate of an N-type transistor having its source connected to the second supply voltage node and to the gate of an N-type transistor having its drain connected to the first supply voltage node.

20. The electronic circuit of claim 19, further comprising a second input node connected to the gate of a P-type transistor having its source connected to the first supply voltage node and to the gate of a P-type transistor having its drain connected to the second supply voltage node, the second input node further being connected to the gate of an N-type transistor having its source connected to the second supply voltage node and to the gate of an N-type transistor having its drain connected to the first supply voltage node.

21. A ring oscillator comprising a plurality of inverters connected to each other in a first loop containing an odd number of the inverters and a second loop containing an odd number of the inverters, each of the inverters in the first loop having its input connected to a buffer that has its output connected to the output of a corresponding inverter in the second loop, and each of the inverters in the second loop having its input connected to a buffer that has its output connected to the output of a corresponding inverter in the first loop.

22. A ring oscillator comprising a plurality of buffers coupled to each other in overlapping multiple loops, and least one of the inverters comprising a buffer connected to the at least one inverter in back-to-back configuration.

23. A memory device, comprising:
a command decoder receiving memory command signals through externally accessible command input terminals, the command decoder generating memory control signals responsive to predetermined combinations of the command signals, the command signals;
an address decoder receiving address signals through externally accessible address input terminals, the address decoder generating row and column addressing signals responsive to the address signals;
a memory array from which data are read and to which data are written at locations corresponding the address signals responsive to the memory control signals;
a data path extending between a plurality of externally accessible data bus terminals and the memory array for coupling write data signals data signals to the memory array and for coupling read data signals from the memory array; and
at least one signal transmitter receiving and then transmitting respective first and second complementary memory command signals, address signals or write data signals, the at least one signal transmitter comprising:
a first inverter having an input receiving the first complementary signal, the first inverter having an output terminal;
a first buffer having an input receiving the second complementary signal, the first buffer having an output terminal coupled to the output terminal of the first inverter;
a second inverter that is substantially identical to the first inverter, the second inverter having an input receiving the second complementary signal, the second inverter having an output terminal; and
a second buffer that is substantially identical to the first buffer, the second buffer having an input receiving the first complementary signal, the second buffer having an output terminal coupled to the output terminal of the second inverter.

24. The memory device of claim 23 wherein each of the first and second inverters comprise:
a P-type transistor having a source connected to a first supply voltage and a drain connected to the output terminal of the inverter; and
an N-type transistor having a drain connected to the output terminal of the inverter and a source connected to a second supply voltage, the second supply voltage having a magnitude that is less than the magnitude of the first supply voltage.

25. The memory device of claim 23 wherein each of the first and second buffers comprise:
an N-type transistor having a drain connected to a first supply voltage and a source connected to the output terminal of the inverter; and
a P-type transistor having a source connected to the output terminal of the inverter and a drain connected to a second supply voltage, the second supply voltage having a magnitude that is less than the magnitude of the first supply voltage.

26. The memory device of claim 23, further comprising:
a third inverter having an input coupled to the output terminal of the first inverter and the output terminal of the first buffer, the third inverter having an output terminal;
a third buffer having an input coupled to the output terminal of the second inverter and the output terminal of the second buffer, the third buffer having an output terminal coupled to the output terminal of the third inverter;
a fourth inverter having an input coupled to the output terminal of the second inverter and the output terminal of the second buffer, the fourth inverter having an output terminal; and
a fourth buffer having an input coupled to the output terminal of the first inverter and the output terminal of the first buffer, the fourth buffer having an output terminal coupled to the output terminal of the fourth inverter.

27. The memory device of claim 23, further comprising:
a third buffer having an input coupled to the output terminal of the first inverter and the output terminal of the first buffer, the third buffer having an output terminal;
a third inverter having an input coupled to the output terminal of the second inverter and the output terminal of the second buffer, the third inverter having an output terminal coupled to the output terminal of the third buffer;
a fourth buffer having an input coupled to the output terminal of the second inverter and the output terminal of the second buffer, the fourth buffer having an output terminal; and
a fourth inverter having an input coupled to the output terminal of the first inverter and the output terminal of the first buffer, the fourth inverter having an output terminal coupled to the output terminal of the fourth buffer.

28. The memory device of claim 23 wherein the first and second complementary memory command signals, address signals or write/read data signals comprise complementary clock signals.

29. A memory device, comprising:
a command decoder receiving memory command signals through externally accessible command input terminals, the command decoder generating memory control signals responsive to predetermined combinations of the command signals, the command signals;
an address decoder receiving address signals through externally accessible address input terminals, the address decoder generating row and column addressing signals responsive to the address signals;
a memory array from which data are read and to which data are written at locations corresponding the address signals responsive to the memory control signals;
a data path extending between a plurality of externally accessible data bus terminals and the memory array for coupling write data signals data signals to the memory array and for coupling read data signals from the memory array; and
a voltage generator receiving a first supply voltage and a second supply voltage, the voltage generator generating from the first and second supply voltages an output voltage having a magnitude that is different from the magnitude of the supply voltage, the voltage generator comprising:
a ring oscillator having a plurality of P-type transistors, a plurality of N-type transistors, a first supply voltage node coupled to receive the first supply voltage, and a second supply voltage node coupled to receive the second supply voltage, the electronic circuit having, for each P-type transistor having a source connected to the first supply voltage node, a correspondingly connected P-type transistor having a drain connected to the second supply voltage node, the electronic circuit further having, for each N-type transistor having a source connected to the second supply voltage node, a correspondingly connected N-type transistor having a drain connected to the first supply voltage node, the ring oscillator generating a periodic signal; and
a charge pump receiving the periodic signal from the ring oscillator, the charge pump generating the output voltage and applying the output voltage to the memory array.

30. The memory device of claim 29 wherein the ring oscillator comprises a plurality of inverters connected to each other in a first loop containing an odd number of the inverters and a second loop containing an odd number of the inverters, each of the inverters in the first loop having its input connected to a buffer that has its output connected to the output of a corresponding inverter in the second loop, and each of the inverters in the second loop having its input connected to a buffer that has its output connected to the output of a corresponding inverter in the first loop.

31. The memory device of claim 29 wherein the memory array has a semiconductor substrate, and wherein the charge pump generates a negative output voltage that is applied to the substrate of the memory array.

32. The memory device of claim 29 wherein the charge pump generates an output voltage having a magnitude that is greater than the magnitude of the first supply voltage and greater than the magnitude of the second supply voltage.

33. A processor-based system, comprising:
a data input device;
a data output device;
a processor coupled to the data input and output devices; and
a memory device coupled to the processor, the memory device comprising,
a command decoder receiving memory command signals through externally accessible command input terminals, the command decoder generating memory control signals responsive to predetermined combinations of the command signals, the command signals;
an address decoder receiving address signals through externally accessible address input terminals, the address decoder generating row and column addressing signals responsive to the address signals;
a memory array from which data are read and to which data are written at locations corresponding the address signals responsive to the memory control signals;
a data path extending between a plurality of externally accessible data bus terminals and the memory array for coupling write data signals data signals to the memory array and for coupling read data signals from the memory array; and
at least one signal transmitter receiving and then transmitting respective first and second complementary memory command signals, address signals or write data signals, the at least one signal transmitter comprising:
a first inverter having an input receiving the first complementary signal, the first inverter having an output terminal;
a first buffer having an input receiving the second complementary signal, the first buffer having an output terminal coupled to the output terminal of the first inverter;
a second inverter that is substantially identical to the first inverter, the second inverter having an input receiving the second complementary signal, the second inverter having an output terminal; and
a second buffer that is substantially identical to the first buffer, the second buffer having an input receiving the first complementary signal, the second buffer having an output terminal coupled to the output terminal of the second inverter.

34. The processor-based system of claim 33 wherein each of the first and second inverters comprise:
a P-type transistor having a source connected to a first supply voltage and a drain connected to the output terminal of the inverter; and
an N-type transistor having a drain connected to the output terminal of the inverter and a source connected to a second supply voltage, the second supply voltage having a magnitude that is less than the magnitude of the first supply voltage.

35. The processor-based system of claim 33 wherein each of the first and second buffers comprise:
an N-type transistor having a drain connected to a first supply voltage and a source connected to the output terminal of the inverter; and
a P-type transistor having a source connected to the output terminal of the inverter and a drain connected to a second supply voltage, the second supply voltage having a magnitude that is less than the magnitude of the first supply voltage.

36. The processor-based system of claim 33, further comprising:
a third inverter having an input coupled to the output terminal of the first inverter and the output terminal of the first buffer, the third inverter having an output terminal;
a third buffer having an input coupled to the output terminal of the second inverter and the output terminal of the second buffer, the third buffer having an output terminal coupled to the output terminal of the third inverter;
a fourth inverter having an input coupled to the output terminal of the second inverter and the output terminal of the second buffer, the fourth inverter having an output terminal; and
a fourth buffer having an input coupled to the output terminal of the first inverter and the output terminal of the first buffer, the fourth buffer having an output terminal coupled to the output terminal of the fourth inverter.

37. The processor-based system of claim 33, further comprising:
a third buffer having an input coupled to the output terminal of the first inverter and the output terminal of the first buffer, the third buffer having an output terminal;
a third inverter having an input coupled to the output terminal of the second inverter and the output terminal of the second buffer, the third inverter having an output terminal coupled to the output terminal of the third buffer;
a fourth buffer having an input coupled to the output terminal of the second inverter and the output terminal of the second buffer, the fourth buffer having an output terminal; and
a fourth inverter having an input coupled to the output terminal of the first inverter and the output terminal of the first buffer, the fourth inverter having an output terminal coupled to the output terminal of the fourth buffer.

38. The processor-based system of claim 33 wherein the first and second complementary memory command signals, address signals or write/read data signals comprise complementary clock signals.

39. A processor-based system, comprising:
a data input device;
a data output device;
a processor coupled to the data input and output devices; and
a memory device coupled to the processor, the memory device comprising,
a command decoder receiving memory command signals through externally accessible command input terminals, the command decoder generating memory control signals responsive to predetermined combinations of the command signals, the command signals;
an address decoder receiving address signals through externally accessible address input terminals, the address decoder generating row and column addressing signals responsive to the address signals;
a memory array from which data are read and to which data are written at locations corresponding the address signals responsive to the memory control signals;
a data path extending between a plurality of externally accessible data bus terminals and the memory array for coupling write data signals data signals to the memory array and for coupling read data signals from the memory array; and
at least one signal transmitter receiving and then transmitting respective first and second complementary memory command signals, address signals or write data signals, the at least one signal transmitter comprising:
a first buffer having an input receiving the first complementary signal, the first buffer having an output terminal;
a first inverter having an input receiving the second complementary signal, the second inverter having an output terminal coupled to the output terminal of the first buffer; and
a second buffer that is substantially identical to the first buffer, the second buffer having an input the second buffer having an input coupled to the output of either the first inverter or the first buffer, the second buffer having an output terminal; and
a second inverter that is substantially identical to the first inverter, the second inverter having an input coupled to the output of either the first inverter or the first buffer, the second inverter having an output terminal;

40. A processor-based system, comprising:
a data input device;
a data output device;
a processor coupled to the data input and output devices; and
a memory device coupled to the processor, the memory device comprising:
a command decoder receiving memory command signals through externally accessible command input terminals, the command decoder generating memory control signals responsive to predetermined combinations of the command signals, the command signals;
an address decoder receiving address signals through externally accessible address input terminals, the address decoder generating row and column addressing signals responsive to the address signals;
a memory array from which data are read and to which data are written at locations corresponding the address signals responsive to the memory control signals;
a data path extending between a plurality of externally accessible data bus terminals and the memory array for coupling write data signals data signals to the memory array and for coupling read data signals from the memory array; and
a voltage generator receiving a first supply voltage and a second supply voltage, the voltage generator generating from the first and second supply voltages an output voltage having a magnitude that is different from the magnitude of the supply voltage, the voltage generator comprising:
a ring oscillator having a plurality of P-type transistors, a plurality of N-type transistors, a first supply voltage node coupled to receive the first supply voltage, and a second supply voltage node coupled to receive the second supply voltage, the electronic circuit having, for each P-type transistor having a source connected to the first supply voltage node, a correspondingly connected P-type transistor having a drain connected to the second supply voltage node, the electronic circuit further having, for each N-type transistor having a source connected to the second supply voltage node, a correspondingly connected N-type transistor having a drain connected to the first supply voltage node, the ring oscillator generating a periodic signal; and
a charge pump receiving the periodic signal from the ring oscillator, the charge pump generating the output voltage and applying the output voltage to the memory array.

41. The processor-based system of claim 40 wherein the ring oscillator comprises a plurality of inverters connected to each other in a first loop containing an odd number of the inverters and a second loop containing an odd number of the inverters, each of the inverters in the first loop having its input connected to a buffer that has its output connected to the output of a corresponding inverter in the second loop, and each of the inverters in the second loop having its input connected to a buffer that has its output connected to the output of a corresponding inverter in the first loop.

42. The processor-based system of claim 40 wherein the memory array has a semiconductor substrate, and wherein the charge pump generates a negative output voltage that is applied to the substrate of the memory array.

43. The processor-based system of claim 40 wherein the charge pump generates an output voltage having a magnitude that is greater than the magnitude of the first supply voltage and greater than the magnitude of the second supply voltage.

44. A processor-based system, comprising:
a data input device;
a data output device;
a processor coupled to the data input and output devices; and
a memory device coupled to the processor, the memory device comprising:
a command decoder receiving memory command signals through externally accessible command input terminals, the command decoder generating memory control signals responsive to predetermined combinations of the command signals, the command signals;
an address decoder receiving address signals through externally accessible address input terminals, the address decoder generating row and column addressing signals responsive to the address signals;
a memory array from which data are read and to which data are written at locations corresponding the address signals responsive to the memory control signals;
a data path extending between a plurality of externally accessible data bus terminals and the memory array for coupling write data signals data signals to the memory array and for coupling read data signals from the memory array; and
a voltage generator receiving a first supply voltage and a second supply voltage, the voltage generator generating from the first and second supply voltages an output voltage having a magnitude that is different from the magnitude of the supply voltage, the voltage generator comprising:
a ring oscillator having a plurality of P-type transistors, A ring oscillator comprising a plurality of buffers coupled to each other in overlapping multiple loops, and least one of the inverters comprising a buffer connected to the at least one inverter in back-to-back configuration; and
a charge pump receiving the periodic signal from the ring oscillator, the charge pump generating the output voltage and applying the output voltage to the memory array.

45. A method of ensuring that complementary signals generated in an electronic circuit having first and second supply voltages are substantially free of signal skew, the method comprising:
for each P-type transistor in the electronic circuit that has a source connected to the first supply voltage, connecting a the drain of corresponding P-type transistor to the second supply voltage; and
for each N-type transistor having a source connected to the second supply voltage node, connecting the drain of a corresponding N-type transistor to the first supply voltage.

46. The method of claim 45 wherein the electronic circuit comprises a signal transmitter.

47. The method of claim 45 wherein the electronic circuit comprises a ring oscillator.

48. The method of claim 45 wherein the electronic circuit comprises a signal generator.
